(19) United States
(12) Patent Application Publication
(10) Pub. No.: US 2026/0324197 A1
(43) Pub. Date: Oct. 15, 2026

(54) DISPLAY DEVICE, METHOD OF MANUFACTURING THE DISPLAY DEVICE, AND ELECTRONIC DEVICE INCLUDING THE DISPLAY DEVICE

(71) Applicant: Samsung Display Co., LTD., Yongin-si (KR)

(72) Inventors: HANBIT KIM, Yongin-si (KR); MEEJAE KANG, Yongin-si (KR); YUNJUNG OH, Yongin-si (KR); DOKYEONG LEE, Yongin-si (KR); SANGGUN CHOI, Yongin-si (KR); Taehyun Hong, Yongin-si (KR)

(21) Appl. No.: 19/407,493

(22) Filed: Dec. 3, 2025

(30) Foreign Application Priority Data
Apr. 14, 2025 (KR) 10-2025-0048059

(51) Int. Cl. H10K 59/121; H10K 59/12

(52) U.S. Cl. CPC H10K 59/1216; H10K 59/1201

(57) ABSTRACT

A display device includes a substrate, a first capacitor electrode disposed on the substrate, an insulating layer covering the first capacitor electrode and including an inorganic insulating material, a second capacitor electrode disposed on the insulating layer and at least partially overlapping the first capacitor electrode in a plan view, and a light emitting element disposed on the second capacitor electrode. The second capacitor electrode includes a first layer including an amorphous silicon and a second layer disposed on the first layer and including a metal or an alloy.

This application claims priority to Korean Patent Application No. 10-2025-0048059, filed on Apr. 14, 2025, and all the benefits accruing therefrom under 35 U.S.C. §119, the content of which in its entirety is herein incorporated by reference.

### BACKGROUND

### 1. Field

Embodiments relate to a display device, a method of manufacturing the display device, and an electronic device including the display device.

### 2. Description of the Related Art

A display device is a device which displays an image to provide visual information to outside the display device, such as to a user. With the development of information technology, the importance of the display device, which is a connecting medium between users and information, is being highlighted. For example, the use of display devices such as a liquid crystal display device (LCD) or an organic light emitting display device (OLED) is increasing.

A display device may include a display area which displays an image. In the display area, pixels which are the smallest units for displaying the image may be disposed. Each of the pixels may include a pixel circuit and a light emitting element connected to the pixel circuit.

### SUMMARY

Embodiments provide a display device with improved reliability.

Embodiments also provide a method of manufacturing a display device with improved reliability.

Embodiments also provide an electronic device with improved reliability.

Additional features of the inventive concepts will be set forth in the description which follows, and in part will be apparent from the description, or may be learned by practice of the inventive concepts.

A display device according to an embodiment includes a substrate, a first capacitor electrode disposed on the substrate, an insulating layer covering the first capacitor electrode and including an inorganic insulating material, a second capacitor electrode disposed on the insulating layer and at least partially overlapping the first capacitor electrode in a plan view, and a light emitting element disposed on the second capacitor electrode. The second capacitor electrode includes a first layer including an amorphous silicon and a second layer disposed on the first layer and including a metal or an alloy.

In an embodiment, the first layer and the second layer may have a same shape in a plan view.

In an embodiment, a thickness of the first layer may range from about 10 angstroms or more to about 1000 angstroms or less.

In an embodiment, a lower surface of the first layer may entirely contact an upper surface of the insulating layer.

In an embodiment, the display device may further include a first transistor including a first electrode to which a driving voltage is applied, a second electrode connected to an anode electrode of the light emitting element, and a gate electrode, a second transistor including a first electrode connected to the gate electrode of the first transistor, a second electrode, and a gate electrode to which a first gate signal is applied, a third transistor including a first electrode connected to the second electrode of the second transistor, a second electrode connected to the second electrode of the first transistor and the anode electrode of the light emitting element, and a gate electrode to which a second gate signal is applied, a first capacitor including a first electrode to which an initialization voltage is applied, and a second electrode connected to the gate electrode of the first transistor and the first electrode of the second transistor, and a second capacitor including a first electrode to which a data voltage is applied, and a second electrode connected to the second electrode of the second transistor and the first electrode of the third transistor.

In an embodiment, the first capacitor electrode may be the second electrode of the first capacitor. The second capacitor electrode may be the first electrode of the first capacitor.

In an embodiment, the first capacitor electrode may be the second electrode of the second capacitor. The second capacitor electrode may the first electrode of the second capacitor.

A method of manufacturing a display device according to an embodiment includes forming a first capacitor electrode on a substrate, forming an insulating layer covering the first capacitor electrode by depositing an inorganic insulating material on the first capacitor electrode, forming a conductive protective layer by depositing an amorphous silicon on the insulating layer, forming a main conductive layer by providing a metal or an alloy on the conductive protective layer, forming a second capacitor electrode by patterning the main conductive layer and the conductive protective layer, and forming a light emitting element on the second capacitor electrode.

In an embodiment, forming the insulating layer and forming the conductive protective layer may use a same type of deposition method. Forming the main conductive layer and forming the conductive protective layer may use different respective types of deposition methods.

In an embodiment, forming the insulating layer and forming the conductive protective layer may use a chemical vapor deposition (CVD) method. Forming the main conductive layer may include using a sputtering method.

In an embodiment, the insulating layer and the conductive protective layer may be continuously formed in a same deposition chamber. During the forming of the insulating layer and the forming of the conductive protective layer, a substrate on which the insulating layer and the conductive protective layer are formed may remain in the deposition chamber.

In an embodiment, forming the insulating layer may further include injecting, by a deposition source in the deposition chamber, a first deposition gas including the inorganic insulating material toward the substrate. Forming the conductive protective layer may further include injecting, by the deposition source, a second deposition gas including the amorphous silicon toward the insulating layer, after the insulating layer is formed.

In an embodiment, the second deposition gas may further include a dopant gas.

In an embodiment, the method may include, after the conductive protective layer is formed, transferring the substrate from the deposition chamber to a sputtering chamber, wherein the main conductive layer may be formed in the sputtering chamber.

In an embodiment, the conductive protective layer may discharge charges accumulated on the insulating layer before the main conductive layer is formed.

In an embodiment, the patterning the main conductive layer and the conductive protective layer may include forming a photoresist pattern on the main conductive layer, and etching the main conductive layer and the conductive protective layer using the photoresist pattern as an etching mask.

In an embodiment, the main conductive layer and the conductive protective layer may be etched using the same photoresist pattern as the etching mask.

In an embodiment, etching the main conductive layer may include using a first etching gas. Etching the conductive protective layer may include using a second etching gas different from the first etching gas and may be after the etching of the main conductive layer.

In an embodiment, the method may include forming the conductive protective layer such that the conductive protective layer has a thickness ranging from about 10 angstroms or more to about 1000 angstroms or less.

An electronic device according to an embodiment includes a display device which displays an image and a processor which provides input image data and an input control signal to the display device. The display device includes a substrate, a first capacitor electrode disposed on the substrate, an insulating layer covering the first capacitor electrode and including an inorganic insulating material, a second capacitor electrode disposed on the insulating layer and at least partially overlapping the first capacitor electrode in a plan view, and a light emitting element disposed on the second capacitor electrode. The second capacitor electrode includes a first layer including an amorphous silicon and a second layer disposed on the first layer and including a metal or an alloy.

According to embodiments, a resolution of the display device may be improved, while improving a reliability of the display device.

It is to be understood that both the foregoing general description and the following detailed description are examples and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the present disclosure, and together with the description serve to explain the invention.

FIG. 1 is a block diagram illustrating a display device according to an embodiment.

FIG. 2 is an equivalent circuit diagram schematically illustrating a pixel according to an embodiment.

FIG. 3 is a cross-sectional view illustrating a display panel according to an embodiment.

FIGS. 4 to 13 are drawings illustrating a method of manufacturing a display device according to an embodiment.

FIG. 14 is a cross-sectional view illustrating a display panel according to an embodiment.

FIG. 15 is a block diagram illustrating an electronic device according to an embodiment.

FIG. 16 is a schematic diagram illustrating an electronic device according to various embodiments.

### DETAILED DESCRIPTION

Various example embodiments will be described more fully hereinafter with reference to the accompanying drawings, in which some example embodiments are illustrated. The present inventive concept may, however, be embodied in many different forms and should not be construed as limited to the example embodiments set forth herein. Rather, these example embodiments are provided such that this disclosure will be thorough and complete, and will fully convey the scope of the embodiments of the present disclosure to those skilled in the art. In the drawings, the sizes and relative sizes of layers and regions may be exaggerated for clarity.

In the disclosure, various modifications can be made, various forms can be used, and specific embodiments will be illustrated in the drawings and described in detail in the text. However, this is not intended to limit the disclosure to a specific form disclosed, and it will be understood that all changes, equivalents, or substitutes which fall in the spirit and technical scope of the disclosure should be included.

It will be understood that, although the terms first, second, third, and the like may be used herein to describe various elements, these elements should not be limited by these terms. These terms are used to distinguish one element from another. Thus, a first element discussed below could be termed a second element without departing from the teachings of the present disclosure. As used herein, the term “and/or” includes any and all combinations of one or more of the associated listed items.

It will be understood that when an element is referred to as being “connected” or “coupled” to another element, it can be directly connected or coupled to the other element or intervening element(s) may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” and the like).

The terminology used herein is for the purpose of describing particular example embodiments and is not intended to be limiting of the embodiments of the present disclosure. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

The terms “about” or “approximately” as used herein are inclusive of the stated value and include a suitable range of deviation for the particular value as determined by one of ordinary skill in the art, considering the measurement in question and the error associated with measurement of the particular quantity. The terms “about” or “approximately” can mean within one or more standard deviations, or within ± 30%, 20%, 10%, 5% of the stated value, for example.

The term “substantially,” as used herein, means approximately or actually. The term “substantially equal” means approximately or actually equal. The term “substantially the same” means approximately or actually the same. The term “substantially perpendicular” means approximately or actually perpendicular. The term “substantially parallel” means approximately or actually parallel.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, embodiments will be described in detail with reference to the accompanying drawings. The same reference numerals are used for the same components in the drawings, and redundant descriptions of the same components will be omitted.

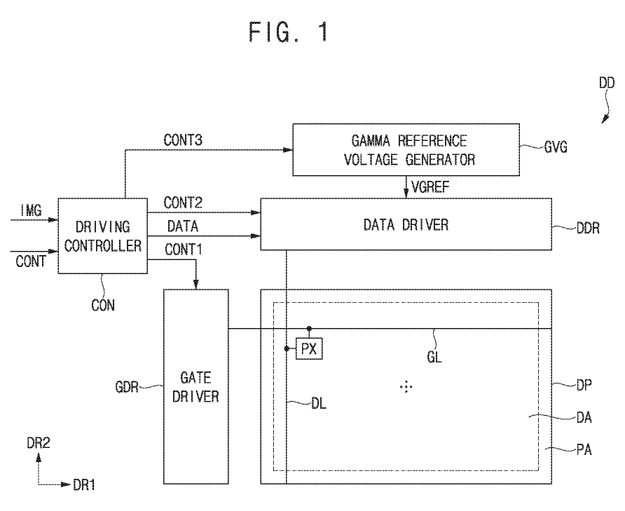

FIG. 1 is a block diagram illustrating a display device according to an embodiment.

Referring to FIG. 1, a display device DD according to an embodiment may include a display panel DP and a panel driver for driving the display panel DP. The panel driver may include a driving controller CON, a gate driver GDR, a gamma reference voltage generator GVG, and a data driver DDR.

In an embodiment, the driving controller CON and the data driver DDR may be integrated. In an embodiment, the driving controller CON, the gamma reference voltage generator GVG, and the data driver DDR may be integrated. In an embodiment, the driving controller CON, the gate driver GDR, the gamma reference voltage generator GVG, and the data driver DDR may be integrated. For example, a driving module which is provided by (e.g., formed by) an integration of at least the driving controller CON and the data driver DDR may be referred to as a timing controller embedded data driver (TED).

The display panel DP may include a display area DA for displaying an image and a peripheral area PA located outside the display area DA. For example, the peripheral area PA may surround at least a portion of the display area DA in a plan view.

In an embodiment, the display panel DP may be an organic light emitting diode display panel including an organic light emitting diode. In an embodiment, the display panel DP may be a quantum dot organic light emitting diode display panel including an organic light emitting diode and a quantum dot color filter. In an embodiment, the display panel DP may be a quantum dot nano light emitting diode display panel including a nano light emitting diode and a quantum dot color filter.

The display panel DP may include a plurality of gate lines GL, a plurality of data lines DL, and a plurality of pixels PX. The plurality of pixels PX may be disposed in the display area DA, and may be electrically connected to the plurality of gate lines GL and the plurality of data lines DL. In an embodiment, each of the gate lines GL may extend generally in a first direction D1. Each of the data lines DL may extend generally in a second direction D2 crossing the first direction D1. For example, the second direction D2 may be perpendicular to the first direction D1.

The driving controller CON may receive input image data IMG and an input control signal CONT from an external host processor (e.g., a processor 12 of FIG. 15). For example, the input image data IMG may include red image data, green image data, and blue image data. For example, the input image data IMG may further include white image data. For example, the input image data IMG may include magenta image data, yellow image data, cyan image data, or the like. The input control signal CONT may include a master clock signal and a data enable signal. The input control signal CONT may further include a vertical synchronization signal and a horizontal synchronization signal.

The driving controller CON may generate a first control signal CONT1, a second control signal CONT2, a third control signal CONT3, and a data signal DATA based on the input image data IMG and the input control signal CONT.

The driving controller CON may generate the first control signal CONT1 for controlling the operation of the gate driver GDR based on the input control signal CONT. The driving controller CON may output the first control signal CONT1 to the gate driver GDR. The first control signal CONT1 may include a vertical start signal and a scan clock signal.

The driving controller CON may generate the second control signal CONT2 for controlling the operation of the data driver DDR based on the input control signal CONT. The driving controller CON may output the second control signal CONT2 to the data driver DDR. The second control signal CONT2 may include a horizontal start signal and a load signal.

The driving controller CON may generate the data signal DATA based on the input image data IMG. The driving controller CON may output the data signal DATA to the data driver DDR.

The driving controller CON may generate the third control signal CONT3 for controlling the operation of the gamma reference voltage generator GVG based on the input control signal CONT. The driving controller CON may output the third control signal CONT3 to the gamma reference voltage generator GVG.

The gate driver GDR may generate gate signals in response to the first control signal CONT1 received from the driving controller CON. The gate driver GDR may output the gate signals to the gate lines GL. In an embodiment, the gate driver GDR may be integrated or mounted on the peripheral area PA of the display panel DP.

The gamma reference voltage generator GVG may generate a gamma reference voltage VGREF in response to the third control signal CONT3 received from the driving controller CON. The gamma reference voltage generator GVG may provide the gamma reference voltage VGREF to the data driver DDR. The gamma reference voltage VGREF may have a value corresponding to each data signal DATA.

In an embodiment, the gamma reference voltage generator GVG may be disposed in the driving controller CON or in the data driver DDR.

The data driver DDR may receive the second control signal CONT2 and the data signal DATA from the driving controller CON, and may receive the gamma reference voltage VGREF from the gamma reference voltage generator GVG. The data driver DDR may convert the data signal DATA into a data voltage in analog form using the gamma reference voltage VGREF. The data driver DDR may output the data voltage to the data line DL.

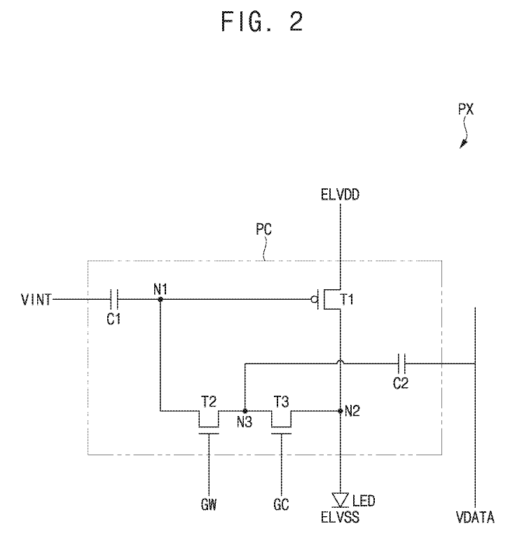

FIG. 2 is an equivalent circuit diagram schematically illustrating a pixel according to an embodiment.

Referring to FIGS. 1 and 2, in an embodiment, the pixel PX may include a pixel circuit PC and a light emitting element LED electrically connected to the pixel circuit PC.

In an embodiment, the pixel circuit PC may include a first transistor T1, a second transistor T2, a third transistor T3, a first capacitor C1, and a second capacitor C2, but the present invention is not limited thereto. In another embodiment, the pixel circuit PC may include two or four or more transistors and/or one or three or more capacitors.

The first transistor T1 may include a gate electrode connected to a first node N1, a first electrode to which a first power voltage ELVDD is applied, and a second electrode connected to a second node N2. The first power voltage ELVDD may be a high power voltage. The first power voltage ELVDD may be referred to as a driving voltage. The first transistor T1 may be referred to as a driving transistor.

The second transistor T2 may include a gate electrode to which a first gate signal GW is applied, a first electrode connected to the first node N1, and a second electrode connected to a third node N3. The second transistor T2 may be referred to as a switching transistor.

The third transistor T3 may include a gate electrode to which a second gate signal GC is applied, a first electrode connected to the third node N3, and a second electrode connected to the second node N2. The third transistor T3 may be referred to as an initialization transistor.

In an embodiment, as illustrated in FIG. 2, the first transistor T1 may be a PMOS, and each of the second transistor T2 and the third transistor T3 may be an NMOS, but the present invention is not limited thereto.

The first capacitor C1 may include a first electrode to which an initialization voltage VINT is applied and a second electrode connected to the first node N1. The first capacitor C1 may be referred to as a storage capacitor.

The second capacitor C2 may include a first electrode to which a data voltage VDATA is applied and a second electrode connected to the third node N3. The second capacitor C2 may be referred to as a program capacitor.

The light emitting element LED may include a first electrode (e.g., an anode electrode) connected to the second node N2 and a second electrode (e.g., a cathode electrode) to which a second power voltage ELVSS is applied. The second power voltage ELVSS may be a low power voltage. The second power voltage ELVSS may be referred to as a common voltage. The light emitting element LED may emit light based on a driving current provided from the pixel circuit PC.

In an embodiment, a driving period of the display panel DP may include an initialization period, a compensation period, a data programming period, and an emission period.

In an embodiment, in the initialization period, each of the second gate signal GC, the initialization voltage VINT, and the data voltage VDATA may have an active level, and each of the first gate signal GW, the driving voltage ELVDD, and the common voltage ELVSS may have a non-active level.

In the initialization period, the third transistor T3 may be turned on and the second transistor T2 may be turned off. For example, the initialization voltage VINT may be changed from a high level to a low level, and the first transistor T1 may be turned on as a voltage of the first node N1 decreases.

In the initialization period, the light emitting element LED may not emit light. For example, the first electrode of the light emitting element LED and the second electrode of the second capacitor C2 may be initialized to a low level of the driving voltage ELVDD.

In an embodiment, in the compensation period, each of the first gate signal GW, the second gate signal GC, the driving voltage ELVDD and the data voltage VDATA may have an active level, and each of the initialization voltage VINT and the common voltage ELVSS may have a non-active level.

In the compensation period, the second transistor T2 and the third transistor T3 may be turned on. The first transistor T1 may be diode-connected by the second and third transistors T2 and T3 which are turned on, such that a threshold voltage of the first transistor T1 may be stored in the first capacitor C1.

In an embodiment, in the data programming period, each of the first gate signal GW and the data voltage VDATA may have an active levels, and each of the second gate signal GC, the driving voltage ELVDD, and the common voltage ELVSS may have a non-active level.

In the data programming period, the second transistor T2 may be turned on, the third transistor T3 may be turned off, and the data voltage VDATA may be stored by charge sharing between the second capacitor C2 and the first capacitor C1. Since the threshold voltage of the first transistor T1 is stored in the first capacitor C1 in the compensation period, in the data programming period, the data voltage VDATA for which the threshold voltage of the first transistor T1 is compensated may be stored in the first capacitor C1.

In the emission period, each of the driving voltage ELVDD and the common voltage ELVSS may have an active level, and each of the first gate signal GW, the second gate signal GC, and the data voltage VDATA may have a non-active level.

A positive voltage may be applied to the light emitting element LED by the driving voltage ELVDD and the common voltage ELVSS. An amount of the driving current flowing through the first transistor T1 may be determined based on the voltage stored in the first capacitor C1 (the data voltage VDATA for which the threshold voltage of the first transistor T1 is compensated), and the light emitting element LED may emit light based on the driving current.

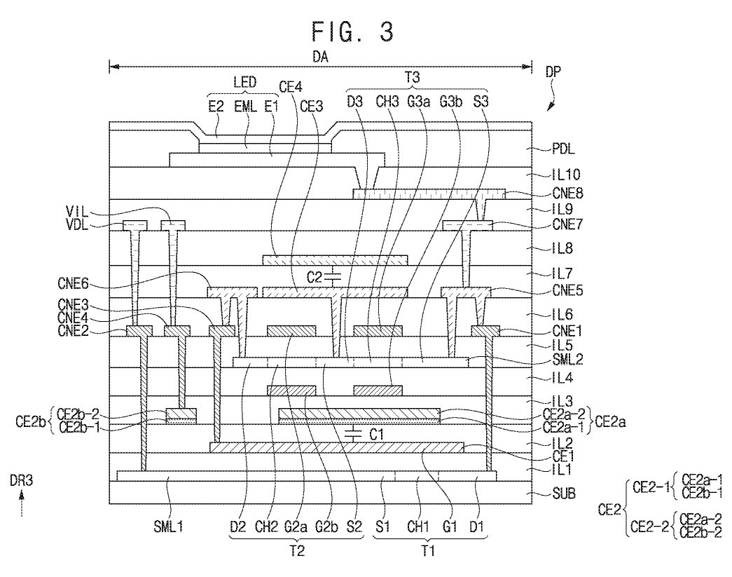

FIG. 3 is a cross-sectional view illustrating a display panel according to an embodiment.

FIG. 3 illustrates an example of a cross-sectional structure of the display area DA of the display panel DP.

Referring to FIGS. 1 to 3, in an embodiment, the display panel DP may include a substrate SUB, first to tenth insulating layers IL1, IL2, IL3, IL4, IL5, IL6, IL7, IL8, IL9, and IL10, the first to third transistors T1, T2, and T3, the first and second capacitors C1 and C2, first to eighth connection electrodes CNE1, CNE2, CNE3, CNE4, CNE5, CNE6, CNE7, and CNE8, a driving voltage line VDL, an initialization voltage line VIL, a pixel defining layer PDL, and the light emitting element LED. Each of the first to third transistors T1, T2, and T3 may include a source area, a drain area, a channel area, and a gate electrode.

The substrate SUB may form a base of the display panel DP. The substrate SUB may be an insulating substrate formed of a transparent or opaque material. The substrate SUB may be flexible or rigid. The substrate SUB may have a single layer structure or a multi-layer structure in which a plurality of layers including different materials are stacked.

The first transistor T1 may be disposed on the substrate SUB. The first transistor T1 may include a source area S1, a drain area D1, a channel area CH1, and a gate electrode G1.

A first semiconductor layer SML1 may be disposed on the substrate SUB. In an embodiment, the first semiconductor layer SML1 may include a silicon semiconductor material. For example, the silicon semiconductor material may include an amorphous silicon, a polycrystalline silicon, or the like.

The first semiconductor layer SML1 may define the source area S1, the drain area D1, and the channel area CH1 between the source area S1 and the drain area D1 of the first transistor T1. The source area S1 and the drain area D1 may have higher conductivity than the channel area CH1. In an embodiment, the source area S1 may be the first electrode of the first transistor T1, and the drain area D1 may be the second electrode of the first transistor T1.

In an embodiment, a buffer layer may be disposed between the substrate SUB and the first semiconductor layer SML1. The buffer layer may prevent or reduce impurities such as oxygen or moisture from penetrating into an upper portion of the substrate SUB through the substrate SUB. The buffer layer may include an inorganic material, such as a silicon compound, a metal oxide, or the like. For example, the buffer layer may include silicon oxide (SiOₓ), silicon nitride (SiNₓ), silicon oxynitride (SiOₓN_{y}), aluminum oxide (AlOₓ), aluminum nitride (AlNₓ), tantalum oxide (TaOₓ), hafnium oxide (HfOₓ), zirconium oxide (ZrOₓ), titanium oxide (TiOₓ), or the like. These may be used alone or in combination with each other. The buffer layer may have a single layer structure or a multi-layer structure including a plurality of insulating layers. In an embodiment, the buffer layer may be omitted.

The first insulating layer IL1 may be disposed on the first semiconductor layer SML1. The first insulating layer IL1 may cover the first semiconductor layer SML1 on the substrate SUB. In an embodiment, the first insulating layer IL1 may include an inorganic insulating material, such as a silicon oxide, a silicon nitride, a silicon oxynitride, a metal oxide, or the like. The first insulating layer IL1 may have a single layer structure or a multi-layer structure including a plurality of insulating layers.

A first capacitor electrode CE1 may be disposed on the first insulating layer IL1. The first capacitor electrode CE1 may include a conductive material, such as a metal or an alloy. The first capacitor electrode CE1 may have a single layer structure or a multi-layer structure including a plurality of conductive layers. For example, the first capacitor electrode CE1 may have a single layer structure of molybdenum (Mo). In another example, the first capacitor electrode CE1 may have a triple-layer structure of titanium (Ti)/aluminum (Al)/titanium (Ti). However, this is an example and the present invention is not limited thereto.

A portion of the first capacitor electrode CE1 (hereinafter, a gate electrode portion) may overlap a portion of the first semiconductor layer SML1 (i.e., the channel area CH1 of the first transistor T1) in a plan view (i.e., in a third direction DR3 which is a thickness direction). The gate electrode portion of the first capacitor electrode CE1 overlapping the channel area CH1 of the first transistor T1 may be the gate electrode G1 of the first transistor T1.

The second insulating layer IL2 may be disposed on the first capacitor electrode CE1. The second insulating layer IL2 may cover the first capacitor electrode CE1 on the first insulating layer IL1. In an embodiment, the second insulating layer IL2 may include an inorganic insulating material, such as a silicon oxide, a silicon nitride, a silicon oxynitride, a metal oxide, or the like. The second insulating layer IL2 may have a single layer structure or a multi-layer structure including a plurality of insulating layers.

A second capacitor electrode CE2 may be disposed on the second insulating layer IL2. In an embodiment, the second capacitor electrode CE2 may include a first layer CE2-1 and a second layer CE2-2 disposed on the first layer CE2-1. The second layer CE2-2 may be disposed directly on the first layer CE2-1. A lower surface of the second layer CE2-2 may directly contact an upper surface of the first layer CE2-1.

The first layer CE2-1 and the second layer CE2-2 may include different conductive materials. The conductivity of the first layer CE2-1 may be different from the conductivity of the second layer CE2-2. In an embodiment, the conductivity of the first layer CE2-1 may be less than the conductivity of the second layer CE2-2.

In an embodiment, the first layer CE2-1 may include an amorphous silicon. The first layer CE2-1 may include an amorphous silicon that is not doped with impurities or an amorphous silicon that is doped with impurities. In an embodiment, the first layer CE2-1 may have a single layer structure.

In an embodiment, the second layer CE2-2 may include a metal or an alloy. The second layer CE2-2 may have a single layer structure or a multi-layer structure including a plurality of conductive layers. For example, the second layer CE2-2 may have a single layer structure of Mo or a triple-layer structure of Ti/Al/Ti, but the present invention is not limited thereto.

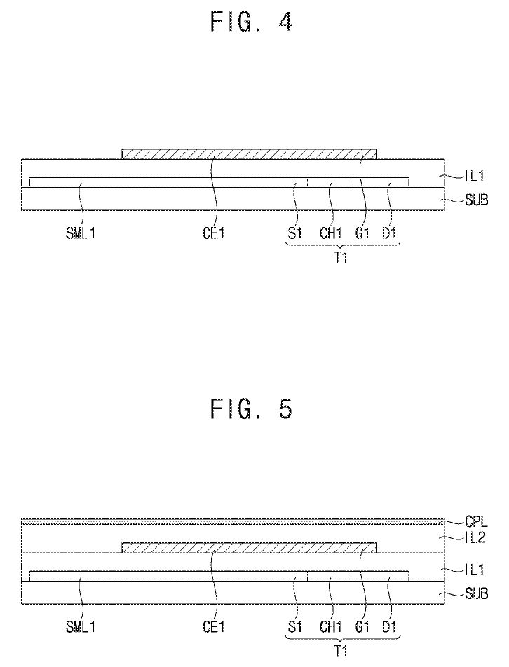

As described herein with reference to FIGS. 4 to 13, the first layer CE2-1 and the second layer CE2-2 may be formed by different types of deposition methods. The first layer CE2-1 may be formed by a same type of deposition method as the second insulating layer IL2. For example, the second insulating layer IL2 and the first layer CE2-1 may be formed by chemical vapor deposition (CVD) method, and the second layer CE2-2 may be formed by a sputtering method, but the present invention is not limited thereto.

In an embodiment, the first layer CE2-1 and the second layer CE2-2 may have substantially the same shape in a plan view. As described herein with reference to FIGS. 4 to 13, the first layer CE2-1 and the second layer CE2-2 may be patterned using a same photoresist pattern as an etching mask.

The second capacitor electrode CE2 may at least partially overlap the first capacitor electrode CE1 in a plan view. In an embodiment, the second capacitor electrode CE2 may include a first portion CE2a and a second portion CE2b. Although the first portion CE2a and the second portion CE2b are illustrated as being separated from each other in FIG. 3, the first portion CE2a and the second portion CE2b may be integrally connected (or integrally provided).

The first portion CE2a of the second capacitor electrode CE2 may include a first layer CE2a-1 and a second layer CE2a-2. The first portion CE2a of the second capacitor electrode CE2 may overlap a portion of the first capacitor electrode CE1 (hereinafter, referred to as a capacitor electrode portion) in a plan view. For example, the capacitor electrode portion of the first capacitor electrode CE1 may include the gate electrode portion. The capacitor electrode portion of the first capacitor electrode CE1, the first portion CE2a of the second capacitor electrode CE2, and the second insulating layer IL2 between the first capacitor electrode CE1 and the second capacitor electrode CE2 may constitute (or form) the first capacitor C1. The capacitor electrode portion of the first capacitor electrode CE1 may be the second electrode of the first capacitor C1, and the first portion CE2a of the second capacitor electrode CE2 may be the first electrode of the first capacitor C1.

The second portion CE2b of the second capacitor electrode CE2 may include a first layer CE2b-1 and a second layer CE2b-2. The second portion CE2b of the second capacitor electrode CE2 may be connected to the initialization voltage line VIL through the fourth connection electrode CNE4. Accordingly, the initialization voltage VINT may be applied to the first portion CE2a of the second capacitor electrode CE2 (i.e., the first electrode of the first capacitor C1) through the second portion CE2b of the second capacitor electrode CE2.

In an embodiment, the second capacitor electrode CE2 may not contact a conductive pattern disposed below the second capacitor electrode CE2. For example, as illustrated in FIG. 3, the second capacitor electrode CE2 may directly contact the fourth connection electrode CNE4 disposed on the second capacitor electrode CE2 through a contact hole, and may not directly contact a conductive pattern disposed below the second capacitor electrode CE2 (e.g., a conductive pattern formed in a same layer as the first semiconductor layer SML1 or the first capacitor electrode CE1). In other words, a lower surface of the second capacitor electrode CE2 (i.e., a lower surface of the first layer CE2-1) may entirely directly contact an upper surface of the second insulating layer IL2. Accordingly, since the first layer CE2-1 of the second capacitor electrode CE2 having relatively low conductivity does not directly contact a conductive pattern disposed below the first layer CE2-1, the first layer CE2-1 may not cause connection failures between elements and/or wirings.

In an embodiment, the first layer CE2-1 of the second capacitor electrode CE2 may serve as a protective layer that prevents or reduces damage (e.g., a dielectric breakdown) of the second insulating layer IL2 due to static electricity during the manufacturing process of the display device DD. This will be described in detail later with reference to FIGS. 4 to 13.

In an embodiment, a thickness of the first layer CE2-1 of the second capacitor electrode CE2 may range from about 10 angstroms or more to about 1000 angstroms or less. If the thickness of the first layer CE2-1 is greater than about 1000 angstroms, a distance between a lower surface of the second layer CE2-2 of the second capacitor electrode CE2, which has higher conductivity than the first layer CE2-1, and an upper surface of the first capacitor electrode CE1 in the third direction DR3 may become excessively large, thereby deteriorating the characteristics of the first capacitor C1.

In an embodiment, a thickness of the second insulating layer IL2 may range from about 40 angstroms or more to about 1400 angstroms or less. For example, a distance between an upper surface of the capacitor electrode portion of the first capacitor electrode CE1 and a lower surface of the first layer CE2a-1 of the first portion CE2a of the second capacitor electrode CE2 in the third direction DR3 may range from about 40 angstroms or more to about 1400 angstroms or less.

As the thickness of the second insulating layer IL2 decreases, the capacitance of the first capacitor C1 increases, but the durability of the second insulating layer IL2 may be weakened. According to a comparative example in which the first layer CE2-1 of the second capacitor electrode CE2 is not formed, if the thickness of the second insulating layer IL2 is equal to or less than about 1400 angstroms or less, the second insulating layer IL2 may be damaged by static electricity during the manufacturing process of the display device DD, thereby causing a defect in the first capacitor C1.

However, according to embodiments, since the first layer CE2-1 of the second capacitor electrode CE2 (a conductive protective layer CPL of FIG. 5) serves as a protective layer that prevents or reduces damage to the second insulating layer IL2 during the manufacturing process of the display device DD, the thickness of the second insulating layer IL2 may be further reduced. Accordingly, while securing the capacitance of the first capacitor C1 (i.e., the storage capacitor), an area of the first capacitor C1 in a plan view may be minimized, thereby improving a degree of integration of the pixel circuit PC. Accordingly, a resolution of the display device DD may be improved, while improving a reliability of the display device DD.

The third insulating layer IL3 may be disposed on the second capacitor electrode CE2. The third insulating layer IL3 may cover the second capacitor electrode CE2 on the second insulating layer IL2. In an embodiment, the third insulating layer IL3 may include an inorganic insulating material, such as a silicon oxide, a silicon nitride, a silicon oxynitride, a metal oxide, or the like. The third insulating layer IL3 may have a single layer structure or a multi-layer structure including a plurality of insulating layers.

The second transistor T2 and the third transistor T3 may be disposed on the third insulating layer IL3. The second transistor T2 may include a source area S2, a drain area D2, a channel area CH2, and a gate electrode G2a. In an embodiment, the second transistor T2 may have a dual gate structure further including a bottom gate electrode G2b. The third transistor T3 may include a source area S3, a drain area D3, a channel area CH3, and a gate electrode G3a. In an embodiment, the third transistor T3 may have a dual gate structure further including a bottom gate electrode G3b.

The bottom gate electrode G2b of the second transistor T2 and the bottom gate electrode G3b of the third transistor T3 may be disposed on the third insulating layer IL3. Each of the bottom gate electrodes G2b and G3b may include a conductive material, such as a metal or an alloy. Each of the bottom gate electrodes G2b and G3b may have a single layer structure or a multi-layer structure including a plurality of conductive layers.

The bottom gate electrode G2b of the second transistor T2 and the bottom gate electrode G3b of the third transistor T3 may be spaced apart from each other. The bottom gate electrode G2b of the second transistor T2 may overlap the channel area CH2 of the second transistor T2 in a plan view, and the bottom gate electrode G3b of the third transistor T3 may overlap the channel area CH3 of the third transistor T3 in a plan view. The first gate signal GW may be applied to the bottom gate electrode G2b of the second transistor T2, and the second gate signal GC may be applied to the bottom gate electrode G3b of the third transistor T3.

The fourth insulating layer IL4 may be disposed on the bottom gate electrodes G2b and G3b. The fourth insulating layer IL4 may cover the bottom gate electrodes G2b and G3b on the third insulating layer IL3. In an embodiment, the fourth insulating layer IL4 may include an inorganic insulating material, such as a silicon oxide, a silicon nitride, a silicon oxynitride, a metal oxide, or the like. The fourth insulating layer IL4 may have a single layer structure or a multi-layer structure including a plurality of insulating layers.

A second semiconductor layer SML2 may be disposed on the fourth insulating layer IL4. In an embodiment, the second semiconductor layer SML2 may include an oxide semiconductor material. For example, the oxide semiconductor material may include an oxide of at least one selected from indium (In), gallium (Ga), tin (Sn), zirconium (Zr), vanadium (V), hafnium (Hf), cadmium (Cd), germanium (Ge), chromium (Cr), titanium (Ti), and zinc (Zn).

The second semiconductor layer SML2 may define the source area S2, the drain area D2, the channel area CH2 between the source area S2 and the drain area D2 of the second transistor T2, the source area S3, the drain area D3, and the channel area CH3 between the source area S3 and the drain area D3 of the third transistor T3. The source areas S2 and S3 and the drain areas D2 and D3 may have higher conductivity than the channel areas CH2 and CH3. In an embodiment, the source area S2 may be the second electrode of the second transistor T2, the drain area D2 may be the first electrode of the second transistor T2, the source area S3 may be the second electrode of the third transistor T3, and the drain area D3 may be the first electrode of the third transistor T3. The source area S2 of the second transistor T2 may be the drain area D3 of the third transistor T3.

The fifth insulating layer IL5 may be disposed on the second semiconductor layer SML2. The fifth insulating layer IL5 may cover the second semiconductor layer SML2 on the fourth insulating layer IL4. In an embodiment, the fifth insulating layer IL5 may include an inorganic insulating material, such as a silicon oxide, a silicon nitride, a silicon oxynitride, a metal oxide, or the like. The fifth insulating layer IL5 may have a single layer structure or a multi-layer structure including a plurality of insulating layers.

The gate electrode G2a of the second transistor T2, the gate electrode G3a of the third transistor T3, the first connection electrode CNE1, the second connection electrode CNE2, the third connection electrode CNE3, and the third connection electrode CNE4 may be disposed on the fifth insulating layer IL5. Each of the gate electrodes G2a and G3a and the first to fourth connection electrodes CNE1, CNE2, CNE3, and CNE4 may include a conductive material, such as a metal or an alloy. Each of the gate electrodes G2a and G3a and the first to fourth connection electrodes CNE1, CNE2, CNE3, and CNE4 may have a single layer structure or a multi-layer structure including a plurality of conductive layers. The gate electrodes G2a and G3a and the first to fourth connection electrodes CNE1, CNE2, CNE3, and CNE4 may be spaced apart from each other.

The gate electrode G2a of the second transistor T2 may overlap the channel area CH2 of the second transistor T2 in a plan view, and the gate electrode G3a of the third transistor T3 may overlap the channel area CH3 of the third transistor T3 in a plan view. The first gate signal GW may be applied to the gate electrode G2a of the second transistor T2, and the second gate signal GC may be applied to the gate electrode G3a of the third transistor T3.

The first connection electrode CNE1 may be connected to the drain area D1 of the first transistor T1 defined in the first semiconductor layer SML1 through a first contact hole.

The second connection electrode CNE2 may be connected to the source area S1 of the first transistor T1 defined in the first semiconductor layer SML1 through a second contact hole.

The third connection electrode CNE3 may be connected to the first capacitor electrode CE1 through a third contact hole.

The fourth connection electrode CNE4 may be connected to the second portion CE2b of the second capacitor electrode CE2 through a fourth contact hole. For example, the fourth connection electrode CNE4 may contact an upper surface of the second layer CEb-2 of the second portion CE2b of the second capacitor electrode CE2 through the fourth contact hole.

The sixth insulating layer IL6 may be disposed on the gate electrodes G2a and G3a and the first to fourth connection electrodes CNE1, CNE2, CNE3, and CNE4. The sixth insulating layer IL6 may cover the gate electrodes G2a and G3a and the first to fourth connection electrodes CNE1, CNE2, CNE3, and CNE4 on the fifth insulating layer IL5. In an embodiment, the sixth insulating layer IL6 may include an inorganic insulating material, such as a silicon oxide, a silicon nitride, a silicon oxynitride, a metal oxide, or the like. The sixth insulating layer IL6 may have a single layer structure or a multi-layer structure including a plurality of insulating layers.

The fifth connection electrode CNE5, the sixth connection electrode CNE6, and a third capacitor electrode CE3 may be disposed on the sixth insulating layer IL6. Each of the fifth connection electrode CNE5, the sixth connection electrode CNE6, and the third capacitor electrode CE3 may include a conductive material, such as a metal or an alloy. Each of the fifth connection electrode CNE5, the sixth connection electrode CNE6, and the third capacitor electrode CE3 may have a single layer structure or a multi-layer structure including a plurality of conductive layers. The fifth connection electrode CNE5, the sixth connection electrode CNE6, and the third capacitor electrode CE3 may be spaced apart from each other.

The fifth connection electrode CNE5 may be connected to the source area S3 of the third transistor T3 defined in the second semiconductor layer SML2 through a fifth contact hole, and may be connected to the first connection electrode CNE1 through a sixth contact hole. Accordingly, the drain area D1 of the first transistor T1 (i.e., the second electrode of the first transistor T1) and the source area S3 of the third transistor T3 (i.e., the second electrode of the third transistor T3) may be electrically connected through the first connection electrode CNE1 and the fifth connection electrode CNE5.

The sixth connection electrode CNE6 may be connected to the drain area D2 of the second transistor T2 defined in the second semiconductor layer SML2 through a seventh contact hole, and may be connected to the third connection electrode CNE3 through an eighth contact hole. Accordingly, the first capacitor electrode CE1 (i.e., the second electrode of the first capacitor C1) and the drain area D2 of the second transistor T2 (i.e., the first electrode of the second transistor T2) may be electrically connected through the third connection electrode CNE3 and the sixth connection electrode CNE6.

The third capacitor electrode CE3 may be connected to the source area S2 of the second transistor T2 and the drain area D3 of the third transistor T3 defined in the second semiconductor layer SML2 through a ninth contact hole.

The seventh insulating layer IL7 may be disposed on the fifth connection electrode CNE5, the sixth connection electrode CNE6, and the third capacitor electrode CE3. The seventh insulating layer IL7 may cover the fifth connection electrode CNE5, the sixth connection electrode CNE6, and the third capacitor electrode CE3 on the sixth insulating layer IL6. In an embodiment, the seventh insulating layer IL7 may include an inorganic insulating material, such as a silicon oxide, a silicon nitride, a silicon oxynitride, a metal oxide, or the like. The seventh insulating layer IL7 may have a single layer structure or a multi-layer structure including a plurality of insulating layers.

A fourth capacitor electrode CE4 may be disposed on the seventh insulating layer IL7. The fourth capacitor electrode CE4 may include a conductive material, such as a metal or an alloy. The fourth capacitor electrode CE4 may have a single layer structure or a multi-layer structure including a plurality of conductive layers.

The fourth capacitor electrode CE4 may at least partially overlap the third capacitor electrode CE3 in a plan view. The third capacitor electrode CE3, the fourth capacitor electrode CE4, and the seventh insulating layer IL7 between the third capacitor electrode CE3 and the fourth capacitor electrode CE4 may constitute (or form) the second capacitor C2. The third capacitor electrode CE3 may be the second electrode of the second capacitor C2, and the fourth capacitor electrode CE4 may be the first electrode of the second capacitor C2. The data voltage VDATA may be applied to the fourth capacitor electrode CE4.

The eighth insulating layer IL8 may be disposed on the fourth capacitor electrode CE4. The eighth insulating layer IL8 may cover the fourth capacitor electrode CE4 on the seventh insulating layer IL7. In an embodiment, the eighth insulating layer IL8 may include an inorganic insulating material, such as a silicon oxide, a silicon nitride, a silicon oxynitride, a metal oxide, or the like. The eighth insulating layer IL8 may have a single layer structure or a multi-layer structure including a plurality of insulating layers.

The seventh connection electrode CNE7, the driving voltage line VDL, and the initialization voltage line VIL may be disposed on the eighth insulating layer IL8. Each of the seventh connection electrode CNE7, the driving voltage line VDL, and the initialization voltage line VIL may include a conductive material, such as a metal or an alloy. Each of the seventh connection electrode CNE7, the driving voltage line VDL, and the initialization voltage line VIL may have a single layer structure or a multi-layer structure including a plurality of conductive layers. The seventh connection electrode CNE7, the driving voltage line VDL, and the initialization voltage line VIL may be spaced apart from each other.

The seventh connection electrode CNE7 may be connected to the fifth connection electrode CNE5 through a tenth contact hole.

The driving voltage ELVDD may be applied to the driving voltage line VDL. The driving voltage line VDL may be connected to the second connection electrode CNE2 through an eleventh contact hole. Accordingly, the driving voltage ELVDD may be applied to the source area S1 of the first transistor T1 (i.e., the first electrode of the first transistor T1).

The initialization voltage VINT may be applied to the initialization voltage line VIL. The initialization voltage line VIL may be connected to the fourth connection electrode CNE4 through a twelfth contact hole. Accordingly, the initialization voltage VINT may be applied to the second capacitor electrode CE2 (i.e., the first electrode of the first capacitor C1).

The ninth insulating layer IL9 may be disposed on the seventh connection electrode CNE7, the driving voltage line VDL, and the initialization voltage line VIL. The ninth insulating layer IL9 may cover the seventh connection electrode CNE7, the driving voltage line VDL, and the initialization voltage line VIL on the eighth insulating layer IL8. In an embodiment, the ninth insulating layer IL9 may include an organic insulating material. For example, the ninth insulating layer IL9 may include a photoresist, a polyacryl-based resin, a polyimide-based resin, a polyamide-based resin, a siloxane-based resin, an acrylic resin, an epoxy-based resin, or the like. These may be used alone or in combination with each other. The ninth insulating layer IL9 may have a single layer structure or a multilayer structure including a plurality of insulating layers.

The eighth connection electrode CNE8 may be disposed on the ninth insulating layer IL9. The eighth connection electrode CNE8 may include a conductive material, such as a metal or an alloy. The eighth connection electrode CNE8 may have a single layer structure or a multilayer structure including a plurality of conductive layers.

The eighth connection electrode CNE8 may be connected to the seventh connection electrode CNE7 through a first via hole.

The tenth insulating layer IL10 may be disposed on the eighth connection electrode CNE8. The tenth insulating layer IL10 may cover the eighth connection electrode CNE8 on the ninth insulating layer IL9. In an embodiment, the tenth insulating layer IL10 may include an organic insulating material. The tenth insulating layer IL10 may have a single layer structure or a multi-layer structure including a plurality of insulating layers.

The light emitting element LED may be disposed on the tenth insulating layer IL10. The light emitting element LED may include a first electrode E1, an emission layer EML, and a second electrode E2.

The first electrode E1 may be disposed on the tenth insulating layer IL10. The first electrode E1 may include a conductive material, such as a metal, an alloy, a conductive metal nitride, a conductive metal oxide, a transparent conductive material, or the like. The first electrode E1 may have a single layer structure or a multi-layer structure including a plurality of conductive layers. The first electrode E1 may be the anode electrode of the light emitting element LED.

The first electrode E1 may be connected to the eighth connection electrode CNE7 through a second via hole. Accordingly, the drain area D1 of the first transistor T1 (i.e., the second electrode of the first transistor T1) and the first electrode E1 of the light emitting element LED may be electrically connected through the first connection electrode CNE1, the fifth connection electrode CNE5, the seventh connection electrode CNE7, and the eighth connection electrode CNE8, and the source area S3 of the third transistor T3 (i.e., the second electrode of the third transistor T3) and the first electrode E1 of the light emitting element LED may be connected through the fifth connection electrode CNE5, the seventh connection electrode CNE7, and the eighth connection electrode CNE8.

The pixel defining layer PDL may be disposed on the first electrode E1. The pixel defining layer PDL may cover a peripheral portion of the first electrode E1, and may define a pixel opening that exposes a central portion of the first electrode E1. An emission area, which is an area where light is emitted from the light emitting element LED, may be defined by the pixel opening. The pixel defining layer PDL may include an organic insulating material. In an embodiment, the pixel defining layer PDL may further include an inorganic material or an organic material including a light blocking material having a black color.

The emission layer EML may be disposed on the first electrode E1 and the pixel defining layer PDL. For example, the emission layer EML may be disposed in the pixel opening of the pixel defining layer PDL. The emission layer EML may include an emission material, such as an organic emission material, an inorganic emission material, or the like.

The second electrode E2 may be disposed on the emission layer EML. The second electrode E2 may also be disposed on the pixel defining layer PDL. For example, the second electrode E2 may be entirely disposed on the display area DA of the display panel DP. The second electrode E2 may include a conductive material, such as a metal, an alloy, a conductive metal nitride, a conductive metal oxide, a transparent conductive material, or the like. The second electrode E2 may have a single layer structure or a multi-layer structure including a plurality of conductive layers. The common voltage ELVSS may be applied to the second electrode E2. The second electrode E2 may be the cathode electrode of the light emitting element LED.

In an embodiment, the light emitting element LED may further include a functional layer disposed between the first electrode E1 and the emission layer EML and/or between the emission layer EML and the second electrode E2. The functional layer may include a hole injection layer, a hole transport layer, an electron transport layer, and/or an electron injection layer.

Although not illustrated in FIG. 3, in an embodiment, the display panel DP may further include various layers, such as a thin film encapsulation layer, a touch sensing layer, an anti-reflection layer, or the like disposed on the second electrode E2.

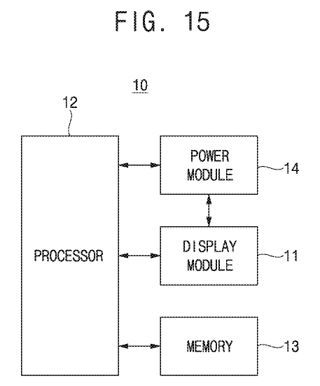

The capacitor structure, in which an upper electrode (i.e., the second capacitor electrode CE2) of the first capacitor C1 includes the first layer CE2-1 including an amorphous silicon and the second layer CE2-2 including a metal or an alloy, according to embodiments described herein may also be applied to other capacitors, such as the second capacitor C2 (see FIG. 14). In some aspects, the capacitor structure is not limited to the display device DD described herein with reference to the circuit diagram of FIG. 2 and the cross-sectional diagram of FIG. 3, and may be applied to capacitors included in display devices having various circuit structures and cross-sectional structures.

FIGS. 4 to 13 are drawings illustrating a method of manufacturing a display device according to an embodiment.

Hereinafter, an embodiment of a method of manufacturing the display device DD of FIGS. 1 to 3 will be described reference to FIGS. 4 to 13.

In the descriptions of the method and processes herein, the operations may be performed in a different order than the order shown and/or described, or the operations may be performed in different orders or at different times. Certain operations may also be left out of the flowcharts, one or more operations may be repeated, or other operations may be added. Descriptions that an element “may be deposited,” “may be formed,” and the like include methods, processes, and techniques for depositing, forming, positioning, and the like in accordance with example aspects described herein.

Referring to FIG. 4, the method may include forming the first semiconductor layer SML1 that defines the source area S1, the drain area D1, and the channel area CH1 of the first transistor T1 on the substrate SUB. The method may include forming the first insulating layer IL1 covering the first semiconductor layer SML1 on the substrate SUB.

The method may include forming the first capacitor electrode CE1 on the first insulating layer IL1. In an embodiment, the method may include forming a preliminary conductive layer by providing a metal or an alloy on the first insulating layer IL1. For example, the preliminary conductive layer may be formed by a sputtering method, but the present invention is not limited thereto. The first capacitor electrode CE1 may be formed by patterning the preliminary conductive layer by a photolithography process and an etching process.

Referring to FIGS. 5 to 7, the method may include forming the second insulating layer IL2 on the first insulating layer IL1, an the second insulating layer IL2 may cover the first capacitor electrode CE1. The method may include forming a conductive protective layer CPL on the second insulating layer IL2.

In an embodiment, the method may include forming the second insulating layer IL2 by depositing an inorganic insulating material on the first insulating layer IL1 and the first capacitor electrode CE1. Subsequently, the method may include forming the conductive protective layer CPL by depositing an amorphous silicon on the second insulating layer IL2.

The second insulating layer IL2 and the conductive protective layer CPL may be formed by the same type of deposition method using the same deposition apparatus 100. For example, the second insulating layer IL2 and the conductive protective layer CPL may be formed by a CVD method, but the present invention is not limited thereto.

In an embodiment, the deposition apparatus 100 may include a deposition chamber 110, a fixing member 120, and a deposition source 130.

The deposition chamber 110 may provide a space in which a deposition process for forming a thin film on a target substrate OS is performed. Here, the target substrate OS may be a structure in which the first semiconductor layer SML1, the first insulating layer IL1, the first capacitor electrode CE1, or the like are formed on the substrate SUB (see FIG. 5).

The fixing member 120 is disposed inside the deposition chamber 110, and may be disposed on the deposition source 130. The fixing member 120 may fix the target substrate OS. The fixing member 120 may include a magnetic body, a jig, a robot arm, or the like for fixing the target substrate OS.

The deposition source 130 may inject a deposition gas including a deposition material. The injected deposition material may be deposited on a surface of the target substrate OS.

In an embodiment, as illustrated in FIGS. 5 to 7, the method may include continuously forming the second insulating layer IL2 and the conductive protective layer CPL in the same deposition chamber 110. During the forming of the insulating layer IL2 and the conductive protective layer CPL, the method may maintain the target substrate OS in the deposition chamber 110 (i.e., the target substrate OS may not be transferred out of the deposition chamber 110). That is, during the forming of the insulating layer IL2 and the conductive protective layer CPL, the target substrate OS may remain located in the deposition chamber 110.

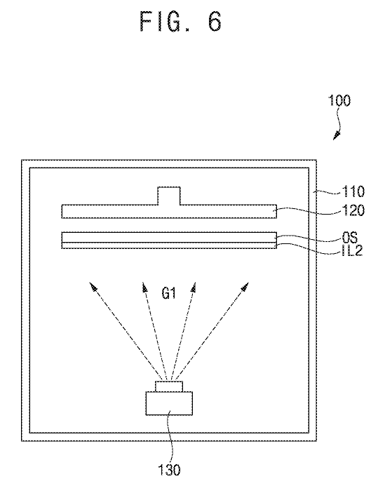

In an embodiment, as illustrated in FIG. 6, in forming the second insulating layer IL2, the deposition source 130 may inject a first deposition gas G1 including an inorganic insulating material (e.g., a silicon nitride) as a deposition material toward the a surface of the target substrate OS. The second insulating layer IL2 may be entirely formed on the surface of the target substrate OS.

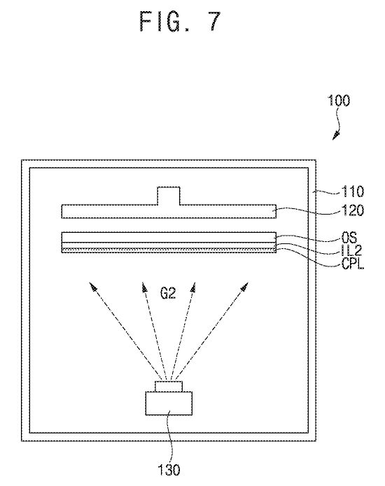

As illustrated in FIG. 7, after the second insulating layer IL2 is formed, the deposition source 130 may inject a second deposition gas G2 including an amorphous silicon as a deposition material toward a surface of the second insulating layer IL2 in association with forming the conductive protective layer CPL. The conductive protective layer CPL may be entirely formed on the surface of the second insulating layer IL2. That is, by changing the deposition gas injected from the deposition source 130 in the same deposition chamber 110, the second insulating layer IL2 and the conductive protective layer CPL may be continuously formed on the target substrate OS.

In an embodiment, the second deposition gas G2 may further include a dopant gas, such as B₂H₆, SiH₄, or the like, in addition to the amorphous silicon, which is the deposition material. For example, by controlling a concentration ratio of the dopant gas, the conductive protective layer CPL, which includes an amorphous silicon and is doped with an impurity, may be formed.

In an embodiment, the conductive protective layer CPL may be formed such that a thickness of the conductive protective layer CPL ranges from about 10 angstroms or more to about 1000 angstroms or less.

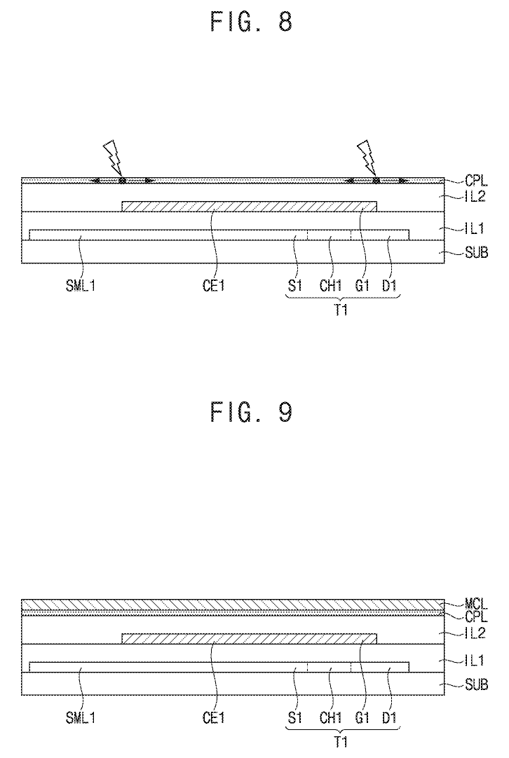

Referring to FIGS. 8 and 9, the method may include forming a main conductive layer MCL on the conductive protective layer CPL.

In an embodiment, the method may include forming the main conductive layer MCL by providing a metal or alloy on the conductive protective layer CPL. The main conductive layer MCL may be formed by a different type of method using an apparatus different from the apparatus used in forming the second insulating layer IL2 and the conductive protective layer CPL. For example, the main conductive layer MCL may be formed by a sputtering method, but the present invention is not limited thereto.

In an embodiment, after the conductive protective layer CPL is formed, the method may include transferring the target substrate OS from the deposition chamber 110 to a sputtering chamber of a sputtering apparatus. At this time, as illustrated in FIG. 8, the conductive protective layer CPL may serve as a protective layer that prevents or reduces damage (e.g., the dielectric breakdown) of the second insulating layer IL2 by static electricity before the main conductive layer MCL is formed.

For example, as illustrated in FIG. 8, during the manufacturing process of the display device DD, such as transferring the target substrate OS to the sputtering chamber, static electricity may be formed on the second insulating layer IL2 and the conductive protective layer CPL. For example, an electric field may be concentrated near edges of the first electrode CE1 due to the static electricity, and charges may be accumulated on the second insulating layer IL2 near the edges of the first electrode CE1. The conductive protective layer CPL may discharge the charges accumulated on the second insulating layer IL2, thereby preventing or reducing the charges from being excessively concentrated in a specific area.

According to a comparative example in which the conductive protective layer CPL is not formed on the second insulating layer IL2 before the target substrate OS is transferred out of the deposition chamber 110, static electricity may be formed on the second insulating layer IL2 due to external friction or induction during the process of transferring the target substrate OS to the sputtering chamber. If static electricity is formed on the second insulating layer IL2 in a state in which the conductive protective layer CPL is not formed, charges may be excessively concentrated near the edges of the first electrode CE1, and the second insulating layer IL2 may be damaged. Therefore, according to the comparative example, in order to prevent damage to the second insulating layer IL2, the thickness of the second insulating layer IL2 should be formed relatively thick (e.g., more than about 1400 angstroms).

However, according to embodiments, the method may include forming the conductive protection layer CPL on the second insulating layer IL2 before the target substrate OS is transferred out of the deposition chamber 110. The conductive protection layer CPL may entirely cover the second insulating layer IL2. Therefore, even if static electricity is formed on the second insulating layer IL2 and the conductive protection layer CPL due to external friction or induction during the process of transferring the target substrate OS to the sputtering chamber, the conductive protection layer CPL may discharge the charges accumulated on the second insulating layer IL2, thereby preventing the charges from being excessively concentrated in a specific area or reducing the amount of charge in the specific area. That is, the conductive protection layer CPL may serve as a protective layer that prevents or reduces damage to the second insulating layer IL2 by static electricity before the main conductive layer MCL is formed. Therefore, embodiments of the present disclosure may include forming the second insulating layer IL2 such that the second insulating layer IL2 is relatively thin (e.g., about 1400 angstroms or less).

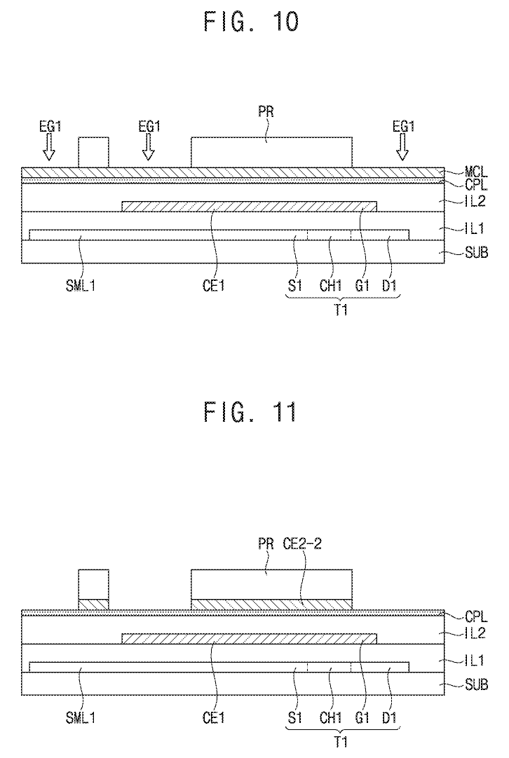

Referring to FIGS. 10 to 13, the method may include forming the second capacitor electrode CE2 by patterning the main conductive layer MCL and the conductive protective layer CPL.

As illustrated in FIG. 10, the method may include forming a photoresist layer on the main conductive layer MCL, and the method may include forming a photoresist pattern PR by exposing and developing the photoresist layer.

As illustrated in FIGS. 11 to 13, the method may include forming the second capacitor electrode CE2 by etching the main conductive layer MCL and the conductive protective layer CPL using the photoresist pattern PR as an etching mask. The main conductive layer MCL and the conductive protective layer CPL may be etched using the same photoresist pattern PR as an etching mask. In an embodiment, the method may include sequentially etching the main conductive layer MCL and the conductive protective layer CPL using different respective etching gases.

In an embodiment, as illustrated in FIGS. 10 and 11, the method may include performing a first dry etching process using a first etching gas EG1, with the photoresist pattern PR used as an etching mask. The first etching gas EG1 may be an etching gas having an etching selectivity with respect to the main conductive layer MCL. That is, the first etching gas EG1 may have a relatively high etching rate for the metal or alloy included in the main conductive layer MCL and a relatively low etching rate for the amorphous silicon included in the conductive protective layer CPL. The main conductive layer MCL may be etched by the first dry etching process to form the second layer CE2-2. In the first dry etching process, the conductive protective layer CPL may be hardly etched (i.e., etching of the conductive protective layer CPL may be relatively minimal).

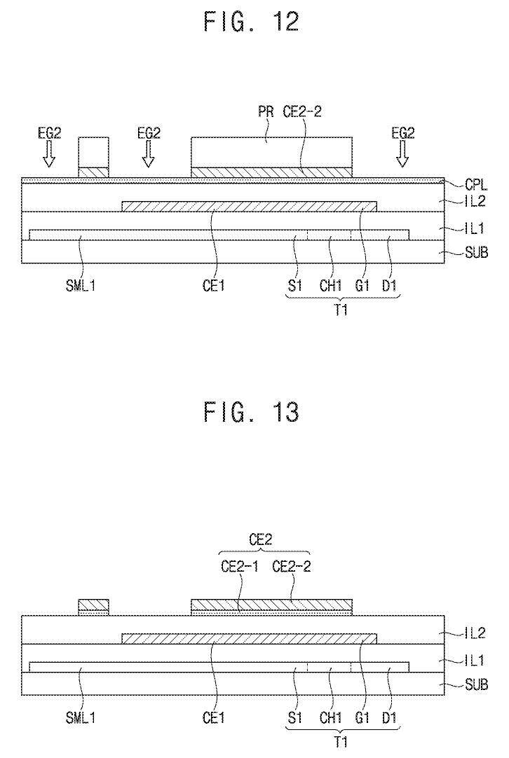

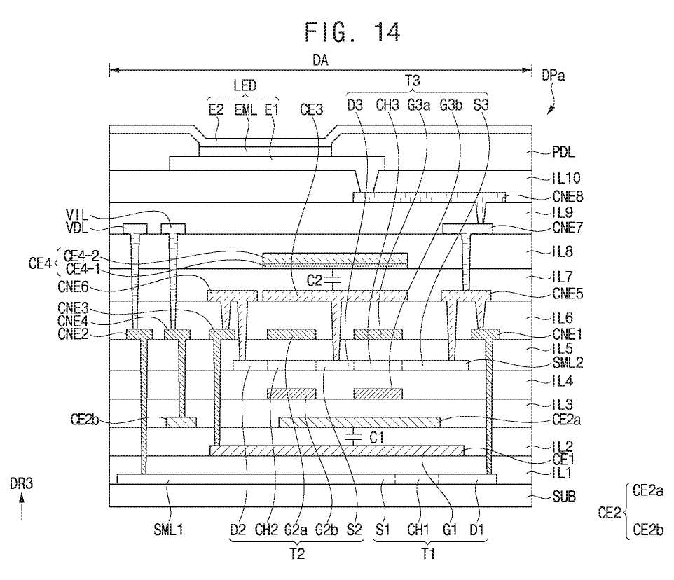

As illustrated in FIGS. 12 and 13, after the first dry etching process, the method may include performing a second dry etching process using a second etching gas EG2, with the photoresist pattern PR used as an etching mask. The second etching gas EG2 may be an etching gas having an etching selectivity with respect to the conductive protective layer CPL. That is, the second etching gas EG2 may have a relatively high etching rate with respect to the amorphous silicon included in the conductive protective layer CPL, and the second etching gas EG2 may have a relatively low etching rate with respect to the metal or alloy included in the main conductive layer MCL and the inorganic insulating material included in the second insulating layer IL2. The conductive protective layer CPL may be etched by the second dry etching process to form the first layer CE2-1. In the second dry etching process, the main conductive layer MCL and the second insulating layer IL2 may be hardly etched (i.e., etching of the main conductive layer MCL and the second insulating layer IL2 may be relatively minimal).

Since the main conductive layer MCL and the conductive protective layer CPL are etched using the same photoresist pattern PR as an etching mask, the first layer CE2-1 and the second layer CE2-2 of the second capacitor electrode CE2 may have substantially the same shape in a plan view.

Subsequently, the third insulating layer IL3 and other configurations on the third insulating layer IL3 of FIG. 3 may be sequentially formed on the second capacitor electrode CE2, thereby manufacturing the display panel DP.

According to embodiments, the second insulating layer IL2 and the conductive protective layer CPL may be continuously formed in the same deposition chamber 110. The conductive protective layer CPL may serve as a protective layer that prevents or reduces damage to the second insulating layer IL2 due to static electricity before the main conductive layer MCL is formed. Since the second insulating layer IL2 can be formed such that the second insulating layer IL2 is relatively thin, while securing the capacitance of the first capacitor C1, the area of the first capacitor C1 in a plan view may be minimized, thereby improving the degree of integration of the pixel circuit PC. Accordingly, the display device DD with improved resolution and improved reliability may be manufactured.

FIG. 14 is a cross-sectional view illustrating a display panel according to an embodiment.

A display panel DPa described herein with reference to FIG. 14 may be substantially the same as or similar to the display panel DP described herein with reference to FIG. 3, except that the first layer CE2-1 of the second capacitor electrode CE2 is omitted and the fourth capacitor electrode CE4 includes the first layer CE4-1 and the second layer CE4-2. Therefore, repeated description will be omitted or simplified.

Referring to FIG. 14, the fourth capacitor electrode CE4 may include a first layer CE4-1 and a second layer CE4-2 disposed on the first layer CE4-1. The second layer CE4-2 may be directly disposed on the first layer CE4-1. A lower surface of the second layer CE4-2 may directly contact an upper surface of the first layer CE4-1.

The first layer CE4-1 and the second layer CE4-2 may include different conductive materials. The conductivity of the first layer CE4-1 may be different from the conductivity of the second layer CE4-2. In an embodiment, the conductivity of the first layer CE4-1 may be less than the conductivity of the second layer CE4-2.

In an embodiment, the first layer CE4-1 may include an amorphous silicon. The first layer CE4-1 may an amorphous silicon that is not doped with impurities or an amorphous silicon that is doped with impurities. In an embodiment, the first layer CE4-1 may have a single layer structure.

In an embodiment, the second layer CE4-2 may include a metal or an alloy. The second layer CE4-2 may have a single layer structure or a multi-layer structure including a plurality of conductive layers. For example, the second layer CE4-2 may have a single layer structure of Mo or a triple-layer structure of Ti/Al/Ti, but the present invention is not limited thereto.

The first layer CE4-1 and the second layer CE4-2 may be formed by different types of deposition methods. The first layer CE4-1 may be formed by a same type of deposition method as the seventh insulating layer IL7. For example, the seventh insulating layer IL7 and the first layer CE4-1 may be formed by CVD method, and the second layer CE4-2 may be formed by a sputtering method, but the present invention is not limited thereto.

In an embodiment, the first layer CE4-1 and the second layer CE4-2 may have substantially the same shape in a plan view.

In an embodiment, as illustrated in FIG. 14, the fourth capacitor electrode CE4 may be disposed such that the fourth capacitor electrode CE4 is not directly contacting a conductive pattern disposed below the fourth capacitor electrode CE4. In other words, a lower surface of the fourth capacitor electrode CE4 (i.e., a lower surface of the first layer CE4-1) may entirely directly contact an upper surface of the seventh insulating layer IL7.

In an embodiment, the first layer CE4-1 of the fourth capacitor electrode CE4 may serve as a protective layer to prevent or reduce damage (e.g., the dielectric breakdown) to the seventh insulating layer IL7 due to static electricity during the manufacturing process of the display device DD.

In an embodiment, a thickness of the first layer CE4-1 of the fourth capacitor electrode CE4 may range from about 10 angstroms or more to about 1000 angstroms or less. If the thickness of the first layer CE4-1 is greater than about 1000 angstroms, a distance between a lower surface of the second layer CE4-2 of the fourth capacitor electrode CE4, which has higher conductivity than the first layer CE4-1, and an upper surface of the third capacitor electrode CE3 in the third direction DR3 may become excessively large, thereby deteriorating the characteristics of the second capacitor C2.

In an embodiment, a thickness of the seventh insulating layer IL7 may range from about 40 angstroms or more to about 1400 angstroms or less. For example, a distance between an upper surface of the third capacitor electrode CE3 and a lower surface of the fourth capacitor electrode CE4 in the third direction DR3 may range from about 40 angstroms or more to about 1400 angstroms or less.

According to the display panel DPa of FIG. 14, since the first layer CE4-1 of the fourth capacitor electrode CE4 serves as a protective layer that prevents or reduces damage to the seventh insulating layer IL7 during the manufacturing process of the display device, the thickness of the seventh insulating layer IL7 may be further reduced. Accordingly, while securing the capacitance of the second capacitor C2 (i.e., the program capacitor), an area of the second capacitor C2 in a plan view may be minimized, thereby improving a degree of integration of the pixel circuit PC. Accordingly, the resolution of the display device DD may be improved, while improving the reliability of the display device DD.

The display device DD according to embodiments may be applied to various electronic devices.

FIG. 15 is a block diagram illustrating an electronic device according to an embodiment.

Referring to FIG. 15, an electronic device 10 according to an embodiment may include a display module 11, a processor 12, a memory 13, and a power module 14.

In an embodiment, the electronic device 10 may include the display device according to embodiments (e.g., the display device DD of FIG. 1) described herein. In an embodiment, the display module 11 may be included in the display device. The electronic device 10 may further include modules or devices with additional functions other than the display device.

The processor 12 may include at least one of a central processing unit (“CPU”), an application processor (“AP”), a graphic processing unit (“GPU”), a communication processor (“CP”), an image signal processor (“ISP”), and a controller.

In an embodiment, the processor 12 may be configured to provide input image data and/or an input control signal to the display device.

The memory 13 may store data information supportive of the operation of the processor 12 or the display module 11. In an example in which the processor 12 executes the application stored in the memory 13, the input image data IMG and/or the input control signal CONT (see FIG. 1) may be transmitted to the display module 11, and the display module 11 may process the received signal and output image information through a display screen.

The power module 14 may include a power supply module, such as a power adapter or a battery device, and a power conversion module which converts the power supplied by the power supply module to generate power for the operation of the electronic device 10.

At least one of each component of the electronic device 10 described herein may be included in the display device according to embodiments. In some aspects, some of the individual modules functionally included in one module may be included in the display device, and other portions may be provided separately from the display device. For example, the display device may include the display module 11, and the processor 12, the memory 13, and the power module 14 may be provided in the form of other devices within the electronic device 10 other than the display device.

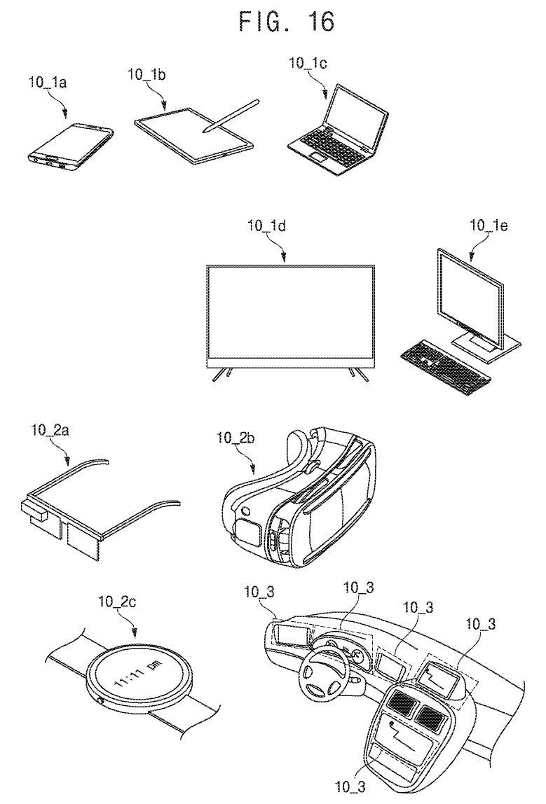

FIG. 16 is a schematic diagram illustrating electronic devices according to various embodiments.

Referring to FIGS. 15 and 16, various electronic devices 10 to which the display device according to embodiments are applied may include not only image display electronic devices such as a smartphone 10_1a, a tablet PC 10_1b, a laptop 10_1c, a TV 10_1d, and a desktop monitor 10_1e, but also wearable electronic devices including display modules, such as smart glasses 10_2a, a head-mounted display 10_2b, and a smart watch 10_2c, automotive electronic devices 10_3 including display modules, such as a dashboard of a car, a center fascia, a Center Information Display (“CID”) disposed on a dashboard, and a room mirror display, or the like. The electronic device 10 is not limited to the image display electronic devices, the wearable electronic devices, and the automotive electronic devices.

Although embodiments and implementations have been described herein, other embodiments and modifications will be apparent from this description. Accordingly, the invention is not limited to such embodiments, but rather to the broader scope of the appended claims and various obvious modifications and equivalent arrangements as would be apparent to a person of ordinary skill in the art.

What is claimed is:

1. A display device comprising:
a substrate;
a first capacitor electrode disposed on the substrate;
an insulating layer covering the first capacitor electrode and comprising an inorganic insulating material;
a second capacitor electrode disposed on the insulating layer, at least partially overlapping the first capacitor electrode in a plan view, and comprising:
a first layer comprising an amorphous silicon; and
a second layer disposed on the first layer and comprising a metal or an alloy; and
a light emitting element disposed on the second capacitor electrode.

2. The display device of claim 1, wherein the first layer and the second layer have a same shape in a plan view.

3. The display device of claim 1, wherein a thickness of the first layer ranges from about 10 angstroms or more to about 1000 angstroms or less.

4. The display device of claim 1, wherein a lower surface of the first layer entirely contacts an upper surface of the insulating layer.

5. The display device of claim 1, further comprising:
a first transistor comprising a first electrode to which a driving voltage is applied, a second electrode connected to an anode electrode of the light emitting element, and a gate electrode;
a second transistor comprising a first electrode connected to the gate electrode of the first transistor, a second electrode, and a gate electrode to which a first gate signal is applied;
a third transistor comprising a first electrode connected to the second electrode of the second transistor, a second electrode connected to the second electrode of the first transistor and the anode electrode of the light emitting element, and a gate electrode to which a second gate signal is applied;
a first capacitor comprising:
a first electrode to which an initialization voltage is applied, and
a second electrode connected to the gate electrode of the first transistor and the first electrode of the second transistor; and
a second capacitor comprising:
a first electrode to which a data voltage is applied, and
a second electrode connected to the second electrode of the second transistor and the first electrode of the third transistor.

6. The display device of claim 5, wherein:
the first capacitor electrode is the second electrode of the first capacitor, and
the second capacitor electrode is the first electrode of the first capacitor.

7. The display device of claim 5, wherein:
the first capacitor electrode is the second electrode of the second capacitor, and
the second capacitor electrode is the first electrode of the second capacitor.

8. A method of manufacturing a display device, the method comprising:
forming a first capacitor electrode on a substrate;
forming an insulating layer covering the first capacitor electrode by depositing an inorganic insulating material on the first capacitor electrode;
forming a conductive protective layer by depositing an amorphous silicon on the insulating layer;
forming a main conductive layer by providing a metal or an alloy on the conductive protective layer;
forming a second capacitor electrode by patterning the main conductive layer and the conductive protective layer; and
forming a light emitting element on the second capacitor electrode.

9. The method of claim 8, wherein:
forming the insulating layer and forming the conductive protective layer use a same type of deposition method, and
forming the main conductive layer and forming the conductive protective layer use different respective types of deposition methods.

10. The method of claim 9, wherein:
forming the insulating layer and forming the conductive protective layer use a chemical vapor deposition (CVD) method, and
forming the main conductive layer comprises using a sputtering method.

11. The method of claim 8, wherein:
the insulating layer and the conductive protective layer are continuously formed in a same deposition chamber, and
during the forming of the insulating layer and the forming of the conductive protective layer, a substrate on which the insulating layer and the conductive protective layer are formed remains located in the deposition chamber.

12. The method of claim 11, wherein:
forming the insulating layer further comprises injecting, by a deposition source in the deposition chamber, a first deposition gas comprising the inorganic insulating material toward the substrate, and
forming the conductive protective layer further comprises injecting, by the deposition source, a second deposition gas comprising the amorphous silicon toward the insulating layer, after the insulating layer is formed.

13. The method of claim 12, wherein the second deposition gas further comprises a dopant gas.

14. The method of claim 11, further comprising, after the conductive protective layer is formed, transferring the substrate from the deposition chamber to a sputtering chamber, wherein the main conductive layer is formed in the sputtering chamber.

15. The method of claim 8, wherein the conductive protective layer discharges charges accumulated on the insulating layer before the main conductive layer is formed.

16. The method of claim 8, wherein the forming the second capacitor electrode by patterning the main conductive layer and the conductive protective layer, comprises:
forming a photoresist pattern on the main conductive layer, and
etching the main conductive layer and the conductive protective layer using the photoresist pattern as an etching mask.

17. The method of claim 16, wherein the main conductive layer and the conductive protective layer are etched using a same photoresist pattern as the etching mask.

18. The method of claim 17, wherein:
etching the main conductive layer comprises using a first etching gas, and
etching the conductive protective layer comprises using a second etching gas different from the first etching gas and is after the etching of the main conductive layer.

19. The method of claim 8, further comprising forming the conductive protective layer such that a thickness of the conductive protective layer ranges from about 10 angstroms or more to about 1000 angstroms or less.

20. An electronic device comprising:
a display device which displays an image and comprises:
a substrate;
a first capacitor electrode disposed on the substrate;
an insulating layer covering the first capacitor electrode and comprising an inorganic insulating material;
a second capacitor electrode disposed on the insulating layer, at least partially overlapping the first capacitor electrode in a plan view, and comprising:
a first layer comprising an amorphous silicon; and
a second layer disposed on the first layer and comprising a metal or an alloy; and
a light emitting element disposed on the second capacitor electrode; and
a processor which provides input image data and an input control signal to the display device.
